(19) United States
(12) Patent Application Publication
(10) Pub. No.: US 2026/0080968 A1
(43) Pub. Date: Mar. 19, 2026

(54) APPARATUSES, SYSTEMS, AND METHODS FOR STORING MEMORY METADATA

(71) Applicant: MICRON TECHNOLOGY, INC., BOISE, ID (US)

(72) Inventor: Sujeet Ayyapureddi, Boise, ID (US)

(73) Assignee: MICRON TECHNOLOGY, INC., Boise, ID (US)

(21) Appl. No.: 19/284,962

(22) Filed: Jul. 30, 2025

Related U.S. Application Data
(60) Provisional application No. 63/695,495, filed on Sep. 17, 2024.

(51) Int. Cl. G11C 29/52; G11C 11/4096; G11C 29/02

(52) U.S. Cl. CPC G11C 29/52; G11C 11/4096; G11C 29/022

(57) ABSTRACT

A bank of a memory device may be divided into column planes. Each column plane may be associated with column selects. In some examples, one or more physical column planes may be selectively configured to store metadata. When the memory device is configured not to store metadata, the column selects may be arranged into virtual column planes to allow data to be stored in physical column planes used for metadata. The physical column planes may be arranged into virtual planes to store the data. Different mapping of the virtual planes to the physical planes may be used.

### CROSS REFERENCE TO RELATED APPLICATION(S)

This application claims the benefit under 35 U.S.C. § 119 of the earlier filing date of U.S. Provisional Application Ser. No. 63/695,495 filed Sep. 17, 2024 the entire contents of which is hereby incorporated by reference in its entirety for any purpose.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

DRAM users are increasingly utilizing metadata to supplement the data stored in the memory array. For example, metadata may be used to store a “poison bit” that indicates that the data associated with the metadata is erroneous and should be discarded and/or replaced by an external device (e.g., controller, host, and/or system on a chip). In another example, metadata may store a pointer to a storage location that may allow the external device to determine what location in the array to access the next associated data. In some applications, this may be analogous to a head and/or tail of a linked list. These are merely examples, and other uses of metadata are also possible.

Metadata may be stored in the memory array in one or more column planes. In some configurations, metadata may be retrieved (e.g., by a controller) along with data and ECC data in a single pass (e.g., a single access operation) as described in U.S. patent application Ser. Nos. 18/504,215, 18/504,302, 18/504,324, and 18/504,353, which are incorporated herein by reference for any purpose. However, in some configurations, addressable memory space may be lost. Some users are sensitive to losing space to store data in order to store metadata. These users may want to give up as little array density as possible while still utilizing metadata. In some configurations, metadata may be retrieved along with data and ECC data in multiple passes as described in U.S. patent application Ser. Nos. 18/430,381, 18/431,306, and 18/441,830, which are incorporated herein by reference for any purpose. Acquiring all of the desired information from the memory device in two passes may allow for more efficient storage of the metadata. However, multiple passes may increase access time, which may reduce performance in some applications. Accordingly, memory devices that can store metadata efficiently and permit single-pass access to the memory array are desired.

### BRIEF DESCRIPTION OF THE DRAWINGS

FIG. 1 is a block diagram of at least a portion of a computing system according to some embodiments of the present disclosure.

FIG. 2 is a block diagram of a semiconductor device according to some embodiments of the present disclosure.

FIG. 3 is a block diagram of a portion of a memory device according to some embodiments of the present disclosure.

FIG. 4 is a block diagram of a portion of a memory device arranged according to some embodiments of the present disclosure.

FIG. 5 is a block diagram of a portion of a memory device arranged according to some embodiments of the present disclosure.

FIG. 6 shows a table indicating physical column plane suppression according to some embodiments of the present disclosure.

FIG. 7 includes a block diagram of a portion of a memory device and a table of a decoding scheme according to some embodiments of the present disclosure.

FIG. 8 shows a table indicating physical column plane suppression according to some embodiments of the present disclosure.

FIG. 9 includes a table of a decoding scheme according to some embodiments of the present disclosure.

FIG. 10 shows a table indicating physical column plane suppression according to some embodiments of the present disclosure.

FIG. 11 shows a table indicating physical column plane suppression for a bounded fault implementation according to some embodiments of the present disclosure.

FIG. 12 is a flow chart of a method according to some embodiments of the present disclosure.

FIG. 13 is a flow chart of a method according to some embodiments of the present disclosure.

FIG. 14 is a flow chart of a method according to some embodiments of the present disclosure.

FIG. 15 is a flow chart of a method according to some embodiments of the present disclosure.

FIG. 16 is a flow chart of a method according to some embodiments of the present disclosure.

FIG. 17 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a cache line.

As discussed in the Background section, memory arrays that can support single-pass access while reducing the loss of addressable memory space in the memory arrays are desired. Further, memory arrays that can be selectively configured to store metadata are desired. For example, some users may not want to utilize metadata and use the memory array space for data instead of metadata.

According to embodiments of the present disclosure, a memory device may include a memory array that is selectively configurable (e.g., enabled) to store metadata. In some embodiments, the memory array may include 16 column planes for data, a column plane for metadata, and a column plane for ECC data (total=18 CP). In some embodiments, the memory array may include 16 column planes for data, two column planes for metadata, and a column plane for ECC data (total=19 CP). Optionally, some embodiments may additionally include a global column redundancy (GCR) plane. When storing metadata is enabled (e.g., by a mode register), in some embodiments, each data column plane is associated with 60 column select signals and the metadata and ECC plane are each associated with 64 column select signals. In some embodiments, each data column plane is associated with 56 column select signals and the metadata planes and ECC plane are each associated with 64 column select signals. When storing metadata is disabled, the column select signals may be activated in a manner such that the memory array operates as if there are sixteen data planes and an ECC data plane (total=17 CP).

Providing one or more additional column planes for metadata may allow metadata to be stored efficiently in the memory array and may permit data, metadata, and ECC data to be retrieved in a single pass. Further, the embodiments disclosed herein may allow flexibility to use the memory array to store metadata or to utilize the metadata space to store data when metadata is not desired.

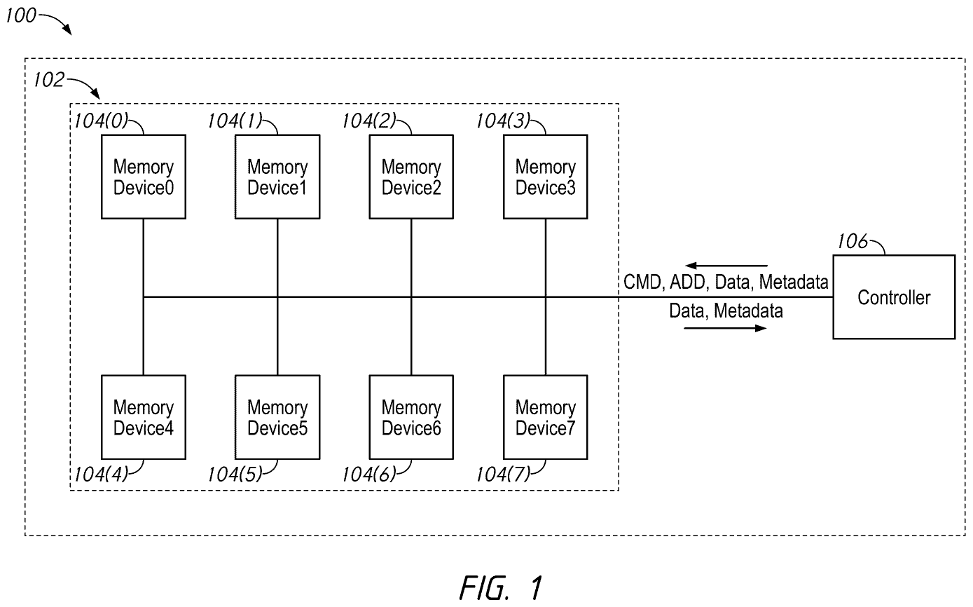

FIG. 1 is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory devices 104. In the example shown in FIG. 1, there are eight memory devices 104(0-7). However, in other embodiments, there may be more or fewer memory devices (e.g., 4 devices, 16 devices). In some embodiments, additional memory devices 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory devices 104.

The controller 106 may provide commands, addresses, and/or data (e.g., data, metadata, or both) to one or more of the memory devices 104 and receive data from one or more of the memory devices 104. In some embodiments, memory devices 104 may be x4 or x8 memory devices. That is, either four or eight DQ terminals (e.g., pins) may be active. In some embodiments, the memory devices 104 may support both x4 and x8 operation. In some embodiments, whether the memory devices 104 operate in x4 or x8 mode may be based, at least in part, on values stored in mode registers (not shown in FIG. 1) of the memory devices 104. In some embodiments, the memory devices 104 may be x16 memory devices.

In some applications, each of the memory devices 104 may provide eight bits of metadata, for a total of four bytes of data. In some applications, each of the memory devices 104 may provide sixteen bits of metadata, for a total of eight bytes of data. The controller 106 may receive cache lines from the memory devices 104 that include 128 bits of data and either 8 bits or 16 bits of metadata. In some embodiments, how much metadata is provided may be based on a value stored in the mode register of the memory device 104.

In some embodiments, whether or not metadata is stored at all may be based on a value stored in the mode register of the memory device 104. For example, when one value is stored in the mode register, metadata may be stored and provided as described herein. When another value is stored in the mode register, metadata may not be stored. When this value is stored, all of the column selects are available for providing data to and from the array. Thus, a same memory may be utilized for applications where metadata is desired and applications where metadata is not desired.

As will be described in more detail herein, when metadata is stored, the physical column planes (e.g., physical planes) of the memory devices 104 associated with data and metadata are accessed by activating the corresponding column select signals for the physical column planes. When metadata is not stored, the memory devices 104 may configure the column select signals to be activated in a manner to form a number of virtual column planes (e.g., virtual planes) to access data. In some embodiments, the number of virtual planes may be less than the number of data and metadata physical planes (e.g., 16 data+1 metadata=17 total physical planes vs. 16 total virtual planes). In some embodiments, the number of bit lines activated on the virtual planes may be equal to the number of bits lines activated in the physical planes during a memory access operation. By “virtual planes” it is meant that column select signals may be activated or suppressed in a manner that does not correspond to the physical planes of the memory array of the memory device 104. However, from the viewpoint of controller 106, the memory devices 104 may receive and output data as if the virtual planes were physical column planes.

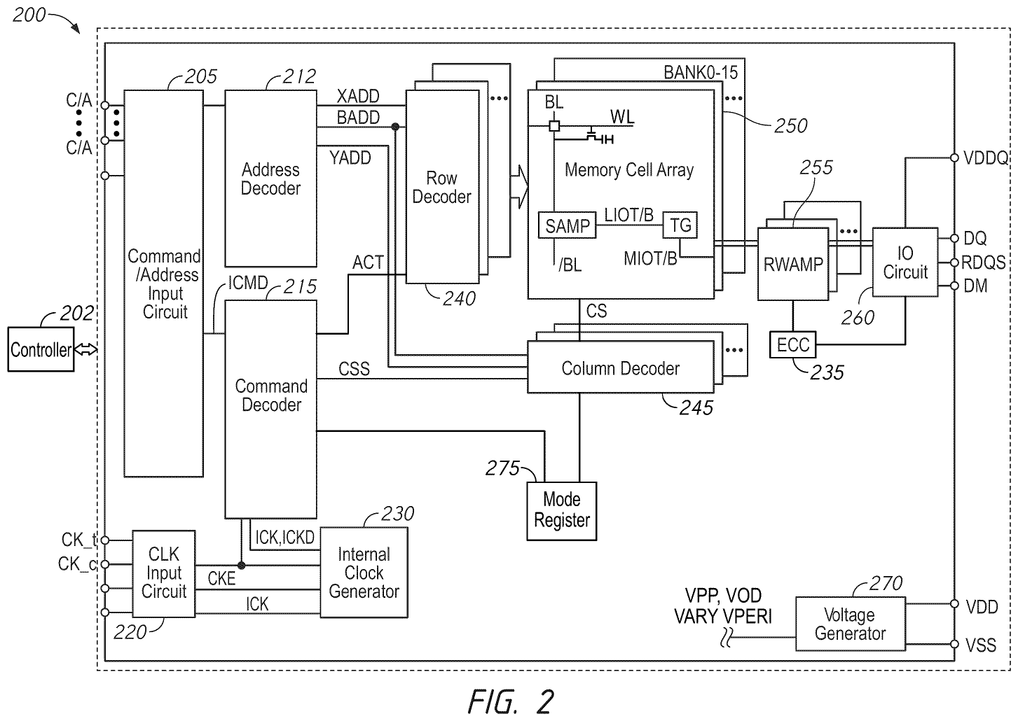

FIG. 2 is a block diagram of a semiconductor device according to some embodiments of the present disclosure. The apparatus may be a semiconductor device 200, and will be referred as such. In some embodiments, the semiconductor device 200 may include, without limitation, a dynamic random access (DRAM) device integrated into a single semiconductor chip. In some examples, the DRAM may be a double data rate (DDR) memory. In some embodiments, one or all of the memory devices 104(0-7) of FIG. 1 may include semiconductor device 200.

The semiconductor device 200 includes a memory die. The die may be mounted on an external substrate, for example, a memory module substrate, a mother board or the like (e.g., package-on-package (POP)). The semiconductor device 200 may further include a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of semiconductor device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The semiconductor device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, VDDQ, and VSSQ.

The C/A terminals may be supplied with an address and a bank address signal from outside, for example, from a controller 202. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, a controller 202. In some embodiments, controller 202 may be implemented or included in controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. Optionally, a further plane may store GCR data. According to embodiments of the present disclosure, the array 250 can be selectively configured to utilize one or more column planes to store metadata.

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword (without the parity bits) is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235may generate ECC data (e.g., a number of parity bits) based on the write data, and the write data and the parity bits may be provided as a codeword to the memory array 250 to be written into the memory cells MC.

The ECC circuit 235 may be used to ensure the fidelity of the data read from a particular group of memory cells to the data written to that group of memory cells. The semiconductor device 200 may include a number of different ECC circuits 235, each of which is responsible for a different portion of the memory cells MC of the memory array 250. For example, there may be one or more ECC circuits 235 for each bank of the memory array 250. Typically, each bank BANK0-15 includes a column plane for the storage of ECC data (e.g., parity bits) and additional column planes for the storage of data (e.g., sixteen column planes). In these applications, the ECC circuit 235 generates eight bits of ECC data (e.g., 8 bits of ECC data) for each cache line of 128 bits. This may allow for the ECC circuit 235 to provide single bit error correction.

The command decoder 215 may access mode register 275 that is programmed with information for setting various modes and features of operation for the semiconductor device 200. For example, the mode register 275 may provide parameters that allow the semiconductor device 200 to operate at different frequencies, provide different burst lengths, allow banks BANK0-15 to be organized into different groups, operate in x4, x8, or x16 mode, and/or other different operating conditions. In some embodiments, mode register 275 may include multiple registers.

The information in the mode register 275 may be programmed by providing the semiconductor device 200 a mode register write command, which causes the semiconductor device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the semiconductor device 200 accordingly. Information programmed in the mode register 275 may be externally provided by the semiconductor device 200 using a mode register read command, which causes the semiconductor device 200 to access the mode register 275 and provide the programmed information (e.g., to the memory controller 202). In some embodiments, the information may be provided via the C/A terminals and/or the DQ terminals.

According to embodiments of the present disclosure, the mode register 275 may be programmed with a value that determines whether or not the semiconductor device 200 stores metadata. When one value is stored in the register, no metadata may be stored (e.g., an operating mode where metadata is disabled). When another value is stored in the register, metadata may also be stored (e.g., an operating mode where metadata is enabled). In some embodiments, the mode register 275 may be programmed with an additional value that determines a number of metadata bits stored.

Based on the values stored in the mode register 275, the mode register may provide one or more signals to the column decoder 245. In some embodiments, the signals from the mode register 275 may enable or disable one or more decoder circuits (or one or more components thereof). The decoder circuits may determine which column select signals are activated and/or physical column planes are accessed during an access operation (e.g., read or write operations).

According to embodiments of the present disclosure, selectively activating or suppressing column select signals associated with one or more physical column planes may allow the formation of virtual column planes. This may allow the semiconductor device 200 to appear to the controller 202 to have a number of column planes different than a number of physical column planes in the array 250.

Turning to the explanation of the external terminals included in the semiconductor device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of semiconductor device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI, and the like and a reference potential ZQVREF based on the power supply potentials VDD and VSS. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

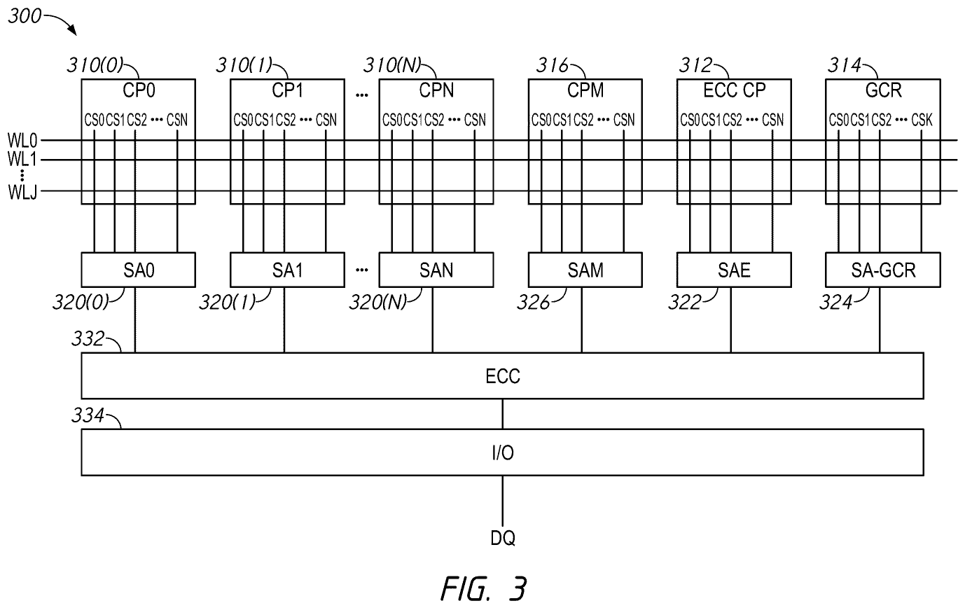

FIG. 3 is a block diagram of a portion of a memory device according to some embodiments of the present disclosure. The memory device 300 may, in some embodiments, represent a portion of the semiconductor device 200 of FIG. 2 or a portion of one or more of the memory devices 104 in FIG. 1. FIG. 3 shows a portion of a memory array 310-316 and 320-326 which may be part of a memory bank (e.g., BANK0-15 of FIG. 2) along with selected circuits used in the data path such as the ECC circuit 332 (e.g., 235 of FIG. 2) and IO circuits 334 (e.g., 260 of FIG. 2). For clarity certain circuits and signals have been omitted from the view of FIG. 3.

The memory device 300 is organized into a number of column planes 310-316. Each of the column planes represents a portion of a memory bank. Each column plane 310-316 includes a number of memory cells at the intersection of word lines WL and bit lines. The bit lines may be grouped together into sets which are activated by a value of a column select (CS) signal. For the sake of clarity, only a single vertical line is used to represent the bit lines of each column select set, however, there may be multiple columns accessed by that value of CS. For example, each line may represent eight bit lines, all accessed in common by a value of CS. As used herein, a ‘value’ of CS may refer to a decoded signal provided to sets of bit lines (e.g., from a column decoder such as 245 in FIG. 2). A first value may represent a first value of a multibit CS signal, or after decoding a signal line associated with that value being active. The word lines may be extended across multiple of the column planes 310-316.

The memory device 300 includes a set of column planes 310 that store data and at least one column plane 316 that stores metadata. The memory device 300 may include an ECC column plane 312 to store ECC information, such as error correction parity bits.

In some embodiments, the memory device 300 may also include an optional global column redundancy (GCR) column plane 314. In some embodiments, the GCR column plane 314 may have fewer memory cells (e.g., fewer column select groups) than the data column planes 310. The GCR CP 314 includes a number of redundant columns which may be used as part of a repair operation. If a value of the CS signal is identified as including defective memory cells in one of the data column planes 310, then the memory may be remapped such that the data which would have been stored in that column plane for that value of CS is instead stored in the GCR CP 314.

In an example embodiment, the memory device 300 may include 16 data column planes 310(0)-310(15) and one metadata column plane 316. When one metadata column plane 316 is included, each of the data column planes 310 includes 60 sets of column selects activated by a value of the column select signal, and the metadata column plane includes 64 sets of column selects activated by a value of the column select signal (e.g., total of 1024 column selects). Each set of column select includes 8 bit lines. Accordingly, when a word line is opened responsive to a row address, and a column select signal is provided to each of the 17 column planes then 8 bits are accessed from each of the 17 column planes for a total of 136 bits (128 data bits and 8 metadata bits). A column select signal is also provided to the ECC column plane 312, although that column select signal may be a different value than the one provided to the column planes 310 for an additional 8 bits. If a repair has been performed, the GCR CP 314 may also be accessed and the value on a GCR LIO may be used while ignoring the LIO of the column plane it is replacing. Accordingly, the maximum number of bits that can be retrieved as part of an access pass is 136 bits from the data column planes 310 (with 8 bits substituted from the GCR CP 314 if there has been a repair) along with 8 additional bits from the ECC CP 312.

In another example, the memory device 300 may include 16 data column planes 310(0)-310(15) and two metadata column planes 316. When two metadata column planes 316 are included, each of the data column planes 310 includes 56 sets of column selects activated by a value of the column select signal, and the metadata column planes include 64 sets of column selects activated by a value of the column select signal (e.g., total of 1024 column selects). Each set of column select includes 8 bit lines. Accordingly, when a word line is opened responsive to a row address, and a column select signal is provided to each of the 18 column planes then 8 bits are accessed from each of the 18 column planes for a total of 144 bits (128 data bits and 16 metadata bits). A column select signal is also provided to the ECC column plane 312, although that column select signal may be a different value than the one provided to the column planes 310 for an additional 8 bits. If a repair has been performed, the GCR CP 314 may also be accessed and the value on a GCR LIO may be used while ignoring the LIO of the column plane it is replacing. Accordingly, the maximum number of bits that can be retrieved as part of an access pass is 128 bits from the data column planes 310 (with 8 bits substituted from the GCR CP 314 if there has been a repair) along with 16 bits from the metadata column planes 316 and 8 additional bits from the ECC CP 312.

During read operations, data may be provided from the column planes 310 to the sense amplifiers 320 to the ECC circuit 332. Metadata may be provided from column plane(s) 316 to sense amplifier(s) 326 and ECC data may be provided from column plane 312 to sense amplifier 322 to the ECC circuit 332. (If a repair has been made, data may also be provided from column plane 314 to sense amplifier 324 to the ECC circuit 332.) The ECC circuit 332 may use the ECC data provided from column plane 312 to correct and/or detect errors in the data and/or metadata. The ECC circuit 332 may output the data and metadata (corrected, if needed) to the I/O circuit 334. The I/O circuit 334 may provide the data and metadata to the DQ. The DQ may make the data and metadata to an external device (e.g., a controller such as 106 in FIGS. 1 and/or 202 in FIG. 2). Optionally, the ECC circuit 332 may further provide error information for output on the DQ.

During write operations, data and metadata may be received by the I/O circuit 334 from the DQ and provide the data and metadata to the ECC circuit 332. Optionally, error information may also be received and provided to the ECC circuit 332. The ECC circuit 332 may generate parity bits and/or other error correction information for the data and metadata. The ECC circuit 332 may provide the data to sense amplifiers 320 for storage in column planes 310. Metadata may be provided to sense amplifier(s) 326 for storage in column plane(s) 316 and the error correction information may be provided to sense amplifier 322 for storage in column plane 312. (If a repair has been made, data may also be provided from the ECC circuit 332 to sense amplifier 324 for storage in column plane 314.)

When the memory device 300, is not configured to store metadata, the controller may be expecting 128 bits of data for a cache line, even if 136 or 144 bits of data can be provided when the metadata column planes 316 are used to store data instead of metadata. However, not using the metadata column planes 316 to store data would reduce the data storage capacity of the memory array that includes the column planes 310-316. Accordingly, when the memory device 300 is configured to not store metadata, the activation of the column selects may be modified to form virtual planes from column planes 310 and 316. The number of virtual planes may be equal to the number of data column planes 310 in some embodiments.

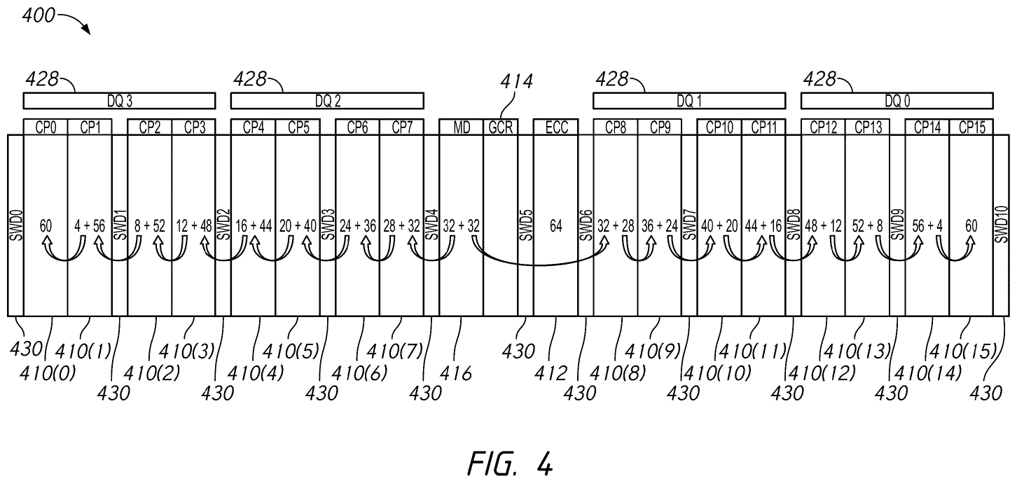

FIG. 4 is a block diagram of a portion of a memory device arranged according to some embodiments of the present disclosure. The memory device 400 may, in some embodiments, represent a portion of the memory device 300 shown in FIG. 3, the semiconductor device 200 of FIG. 2, and/or one or more of the memory devices 104 shown in FIG. 1. FIG. 4 shows a portion of a memory array 410-416 which may be part of a memory bank (e.g., BANK0-15 of FIG. 2) along with selected circuits used in the data path such as the subword line drivers SWD) 430 and DQ 428.

The memory device 400 has several physical column planes in a bank. In the example shown in FIG. 4, there are sixteen data column planes 410(0-15) (CP0-15), a metadata column plane 416 (MD), an ECC column plane 412, and a GCR plane 414. These column planes may correspond to column planes 310-316 in some embodiments.

The metadata column plane 416 may be associated with 64 column select signals and the data column planes 410 may each be associated with 60 column select signals. When no metadata is stored in the memory array, it may be desirable to have each data column plane 410 associated with 64 column select signals instead of 60.

In the embodiment shown in FIG. 4, varying numbers of column select signals are “borrowed” from other physical column select planes. For example, CP0 borrows 4 CS from CP1 to form a virtual CP0 associated with 64 CS, CP1 borrows 12 CS from CP2 to form a virtual CP1 associated with 64 CS, and so on. CP7 borrows 32 CS from the metadata column plane 416 to form a virtual CP7, and CP8 borrows the remaining 32 CS from the metadata column plane 416 to form a virtual CP8. CP8 “lends” 28 CS to CP9, and CP9 lends 24 CS to CP10, and so on to form virtual planes each associated with 64 CS. As shown, the metadata column plane 416 lends all of its column select signals to the virtual data column planes, so there are no longer any column select signals associated with the metadata column plane 416. So, all of the virtual data column planes are associated with 64 column select signals.

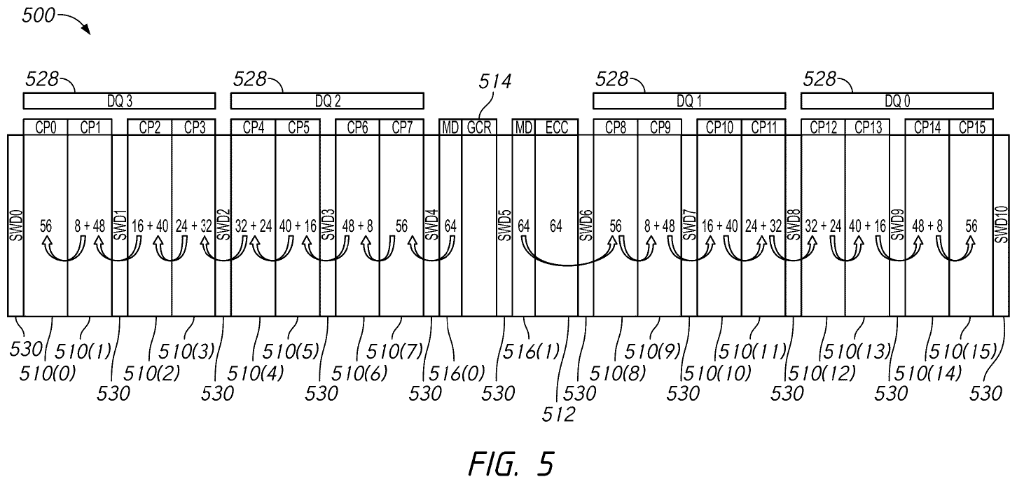

FIG. 5 is a block diagram of a portion of a memory device arranged according to some embodiments of the present disclosure. The memory device 500 may, in some embodiments, represent a portion of the memory device 300 shown in FIG. 3, the semiconductor device 200 of FIG. 2, and/or one or more of the memory devices 104 shown in FIG. 1. FIG. 5 shows a portion of a memory array 510-516 which may be part of a memory bank (e.g., BANK0-15 of FIG. 2) along with selected circuits used in the data path such as the subword line drivers 530 and DQ 528.

The memory device 500 has several physical column planes in a bank. In the example shown in FIG. 5, there are sixteen data column planes 510(0-15) (CP0-15), two metadata column planes 416(0-1) (MD), an ECC column plane 512, and a GCR plane 414. These column planes may correspond to column planes 310-316 in some embodiments.

The metadata column planes 516 may each be associated with 64 column select signals and the data column planes 510 may each be associated with 56 column select signals. When no metadata is stored in the memory array, it may be desirable to have each data column plane 510 associated with 64 column select signals instead of 56.

In the embodiment shown in FIG. 5, varying numbers of column select signals are “borrowed” from other physical column select planes. For example, CP0 borrows 8 CS from CP1 to form a virtual CP0 associated with 64 CS, CP1 borrows 16 CS from CP2 to form a virtual CP1 associated with 64 CS, and so on. CP7 borrows 64 CS from the metadata column plane 516(0) to form a virtual CP7. CP8 borrows the 64 CS from the metadata column plane 416(1) to form a virtual CP8. CP8 “lends” 56 CS to CP9, and CP9 lends 48 CS to CP10, and so on to form virtual planes each associated with 64 CS. As shown, the metadata column planes 416(0-1) lend all of their column select signals to the virtual data column planes, so there are no longer any column select signals associated with the metadata column planes 416(0-1). So, all of the virtual data column planes are associated with 64 column select signals.

When a memory device is not storing metadata, even though the memory device is capable of providing more than 128 bits of data per cache line because of the additional physical column planes, an external device, such as a controller (e.g., controller 106 and/or 202), may not be configured to receive more than 128 bits of data. Accordingly, when the memory device is configured to use virtual planes, for example, as shown in FIGS. 4 and 5, the column select signals for one or more physical column planes may be suppressed in order to output the expected amount of data (e.g., 128 bits) from the virtual planes. In the example shown in FIG. 4, column selects associated with one physical plane may be suppressed to prevent the memory from providing 136 bits of data. In the example shown in FIG. 5, column selects associated with two physical column planes may be suppressed to prevent the memory from providing 144 bits of data.

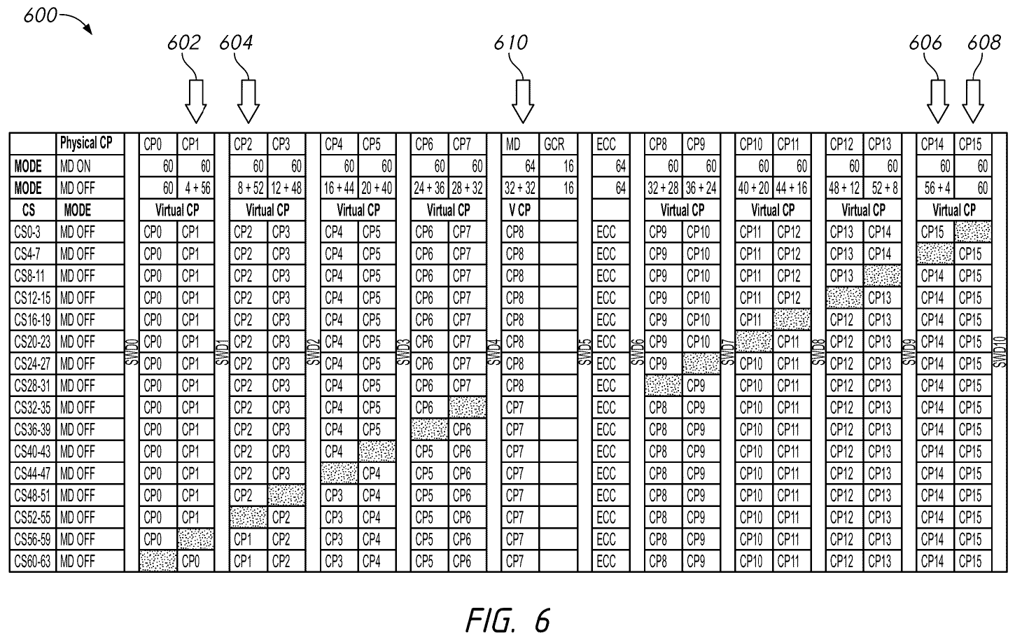

FIG. 6 shows a table indicating physical column plane suppression according to some embodiments of the present disclosure. The suppression scheme depicted in table 600 may be used when a memory (e.g., one or more of memory devices 104 and/or semiconductor device 200) is configured as described with reference to FIG. 4 in some embodiments.

The top line of table 600 indicates the physical column planes. The next line indicates the number of column selects in each of the physical planes, and that the memory device operates using the physical planes when the memory device is in an operating mode where metadata is stored (MD ON). The third line indicates the arrangement of the column selects when the memory device is in an operating mode where metadata is not stored (MD OFF) as was shown in FIG. 4.

Below the top three rows are several columns providing more details on the physical column plane suppression scheme. The first column indicates the column selects (CS) and the second column indicates the operating mode of the memory device (MODE). The mode is MD OFF (no metadata stored) for the entire column. When metadata is stored, physical column planes may not be suppressed in some embodiments. The vertical bars separating columns indicate the locations of subword line drivers (SWD0-10) relative to the physical column planes. The SWD may be included in SWD 430 in some embodiments.

The remaining columns of table 600 indicate the column select signals (CS) of a physical plane that are associated with a given virtual plane. For example, in the case of the MD OFF mode, looking at the column indicated by arrow 602, CS0-55 of physical CP1 are associated with virtual CP1, but CS60-63 of physical CP1 are associated with virtual CP0. CS56-59 of physical CP1 are not associated with any virtual planes. Looking at the next column indicated by arrow 604, the remaining CS for virtual CP1 are included in CS56-63 of physical CP2.

The filled in boxes in table 600 indicate the column selects of a physical plane that are not associated with any virtual plane. These column selects of a physical plane should be suppressed during a memory access operation. For example, say CS0, CS1, CS2, and/or CS3 are activated (e.g., by a column decoder, such as 245 in FIG. 2). Looking at the last two columns of table 600, virtual CP15 is formed by CS0-3 of physical CP14 as seen in the column indicated by arrow 606, and CS4-63 of physical CP15 as seen in the column indicated by arrow 608. Thus, CS0-3 of physical CP15 is not associated with any virtual plane. Accordingly, the activating of CS0-3 in physical CP15 should be suppressed. Similarly, virtual CP14 is associated with CS0-7 of physical CP 13 and CS8-63 of physical CP14. As seen in the column indicated by arrow 606, CS4-7 of physical CP14 is not associated with any virtual plane. Accordingly, the activating of CS4-7 should be suppressed for physical CP14.

The column indicated by arrow 610 is for the physical metadata plane. Note that unlike the physical data column planes that are associated with 60 column select signals, the metadata plane is associated with 64 column select signals. Further, all of the column select signals of the metadata plane are “lent” to virtual data planes in the MD OFF mode (CP7 and CP8 in the example shown). Accordingly, all of the column selects of the physical metadata plane are associated with virtual planes, and none of the column selects in the metadata plane are suppressed. Similarly, in the example shown in FIG. 6, no suppression of column selects in the physical ECC plane is provided.

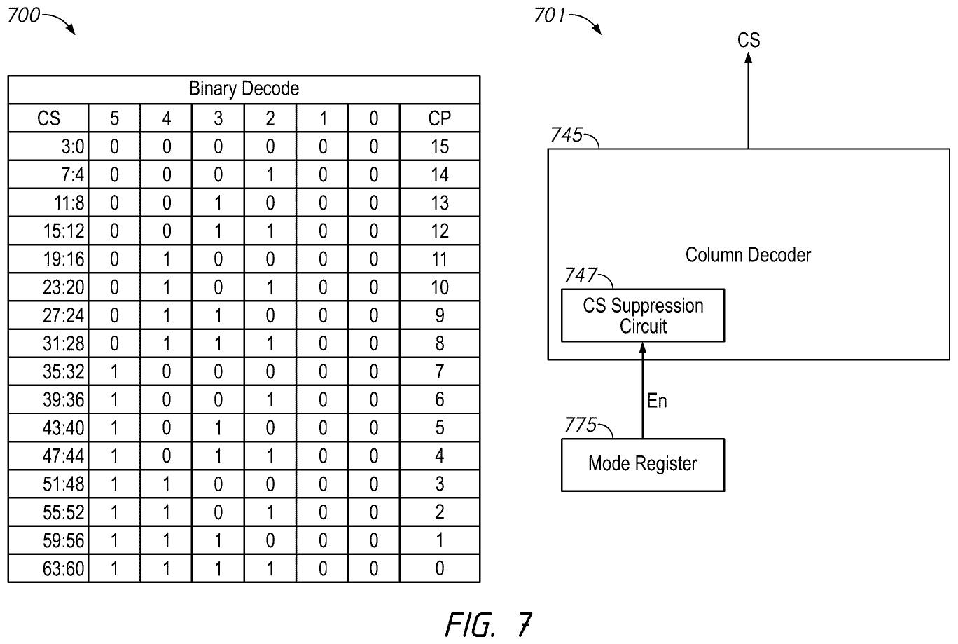

FIG. 7 includes a block diagram of a portion of a memory device and a table of a decoding scheme according to some embodiments of the present disclosure. Memory device 701 may be included as a portion of one or more of memory devices 104 in FIG. 1 and/or semiconductor device 200 in FIG. 2. Memory device 701 includes a column decoder 745 that includes a column select (CS) suppression circuit. Column decoder 745 may be used to implement or may be included in column decoder 245 in some embodiments. Memory device 701 includes a mode register 775. In some embodiments, the mode register 775 may be used to implement or may be included in mode register 275.

Mode register 775 may be programmed with one or more values to set operating modes and/or parameter for the operation of memory device 701. For example, the mode register 775 may be programmed with a value in a first state that indicates metadata is stored in a memory array (e.g., memory array 250). When metadata is stored in the memory array, the mode register 775 may provide an inactive enable signal En to the CS suppression circuit 747 such that the column decoder does not suppress the activation of any column selects in physical column planes. The mode register 775 may be programmed with the value in a second state that indicates metadata is not stored in the memory array. When metadata is not stored in the memory array, the mode register 775 may provide an active En signal to the CS suppression circuit 747 to suppress the column selects of certain physical column planes.

In some embodiments, the CS suppression circuit 747 may include one or more logic circuits to implement a decoding scheme to provide the desired suppression of column selects when enabled. For example, the CS suppression circuit 747 may include decoding logic to implement the suppression scheme described with reference to FIG. 6. In some embodiments, the CS suppression circuit 747 may include one or more logic circuits that implement a binary decoding scheme shown in table 700.

The first column of table 700 indicates the column select signals (CS). The next six columns indicate the binary inputs to be decoded. The final column indicates the physical column plane (CP) for which the indicated CS is suppressed. The first four inputs may be used to indicate the CP (the columns labeled 5-2) to be suppressed. The CS suppression circuit 747 may invert the first four inputs to determine the physical column plane to suppress CS activation for a particular CS. For example, in the row for CS3:0, the inputs are “0000.” Inverted, this is “1111,” which corresponds to fifteen. Accordingly, as indicated by the final column, CS activation in physical CP15 is suppressed when CS0, CS1, CS2, or CS3 is selected for activation. This matches FIG. 6, where CS0-3 of CP15 are blocked out.

Any suitable logic circuits may be used to implement table 700 in CS suppression circuit 747. In some embodiments, the remaining two inputs (the columns labeled 1-0) may be omitted. In other embodiments, the remaining to inputs may be used to provide additional information to the CS suppression circuit 747 and/or other components of the column decoder 745.

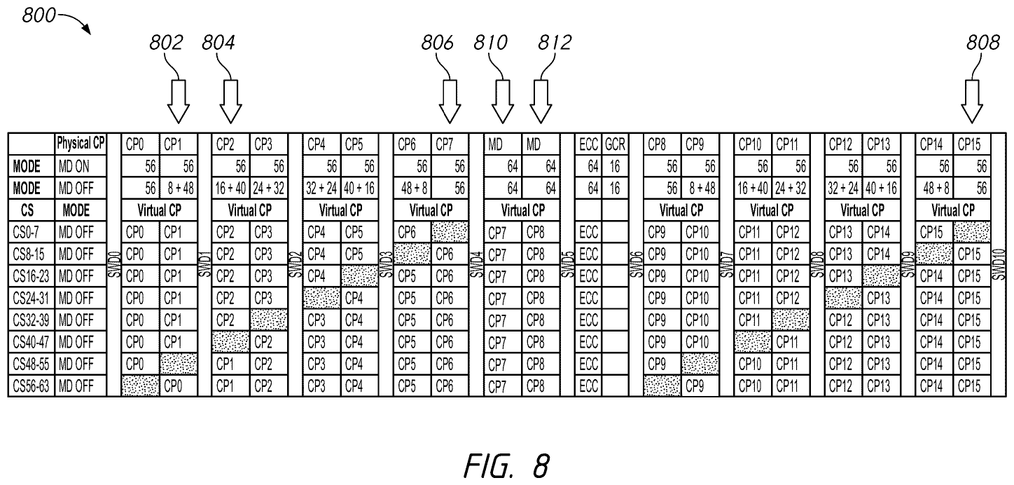

FIG. 8 shows a table indicating physical column plane suppression according to some embodiments of the present disclosure. The suppression scheme depicted in table 800 may be used when a memory (e.g., one or more of memory devices 104 and/or semiconductor device 200) is configured as described with reference to FIG. 5 in some embodiments.

The top line of table 800 indicates the physical column planes. The next line indicates the number of column selects in each of the physical planes, and that the memory device operates using the physical planes when the memory device is in an operating mode where metadata is stored (MD ON). The third line indicates the arrangement of the column selects when the memory device is in an operating mode where metadata is not stored (MD OFF) as was shown in FIG. 5.

Below the top three rows are several columns providing more details on the physical column plane suppression scheme. The first column indicates the column selects (CS) and the second column indicates the operating mode of the memory device (MODE). The mode is MD OFF (no metadata stored) for the entire column. When metadata is stored, physical column planes may not be suppressed in some embodiments. The vertical bars separating columns indicate the locations of subword line drivers (SWD0-10) relative to the physical column planes. The SWD may be included in SWD 430 in some embodiments.

The remaining columns of table 800 indicate the column select signals (CS) of a physical plane that are associated with a given virtual plane. For example, looking at the column indicated by arrow 802, CS0-47 of physical CP1 are associated with virtual CP1, but CS56-63 of physical CP1 are associated with virtual CP0. CS48-55 of physical CP1 are not associated with any virtual plane. Looking at the next column indicated by arrow 804, the remaining CS for virtual CP1 are included in CS48-63 of physical CP2.

The filled in boxes in table 800 indicate the column selects of a physical plane that are not associated with any virtual plane. These column selects of a physical plane should be suppressed during a memory access operation. In contrast to the scheme shown in FIG. 6, the column selects for two physical planes are suppressed. This is due, at least in part, to the arrangement of the memory array to include two metadata planes (in the columns indicated by arrows 810, 812) in contrast to one metadata plane as shown in FIG. 5. For example, say any or all of CS0-7 are activated (e.g., by a column decoder, such as 245 in FIG. 2). Looking at the columns indicated by arrows 806 and 808, the CS0-7 of physical columns CP7 and CP15 are not associated with any virtual planes. Accordingly, the activating of CS0-7 in physical CP7 and CP15 should be suppressed.

As discussed previously, unlike the physical data column planes that are associated with 56 column select signals, the metadata planes are associated with 64 column select signals. Further, all of the column select signals of the metadata planes are “lent” to virtual data planes in the MD OFF mode (CP7 and CP8 in the example shown). Accordingly, all of the column selects of the physical metadata plane are associated with virtual planes, and none of the column selects in the metadata plane are suppressed. Similarly, in the example shown in FIG. 8, no suppression of column selects in the physical ECC plane is provided.

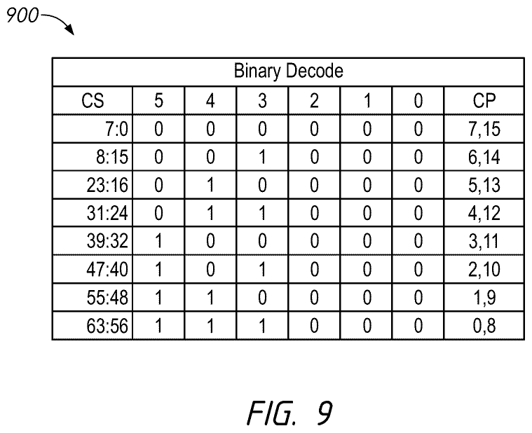

FIG. 9 includes a table of a decoding scheme according to some embodiments of the present disclosure. In some embodiments, the decoding scheme shown in FIG. 9 may be implemented by the memory device 701 shown in FIG. 7.

Mode register 775 may be programmed with one or more values to set operating modes and/or parameter for the operation of memory device 701. For example, the mode register 775 may be programmed with a value in a first state that indicates metadata is stored in a memory array (e.g., memory array 250). When metadata is stored in the memory array, the mode register 775 may provide an inactive enable signal En to the CS suppression circuit 747 such that the column decoder does not suppress the activation of any column selects in physical column planes. The mode register 775 may be programmed with the value in a second state that indicates metadata is not stored in the memory array. When metadata is not stored in the memory array, the mode register 775 may provide an active En signal to the CS suppression circuit 747 to suppress the column selects of certain physical column planes.

In some embodiments, the CS suppression circuit 747 may include one or more logic circuits to implement a decoding scheme to provide the desired suppression of column selects when enabled. For example, the CS suppression circuit 747 may include decoding logic to implement the suppression scheme described with reference to FIG. 8. In some embodiments, the CS suppression circuit 747 may include one or more logic circuits that implement a binary decoding scheme shown in table 900.

The first column of table 900 indicates the column select signals (CS). The next six columns indicate the binary inputs to be decoded. The final column indicates the physical column planes (CP) for which the indicated CS are suppressed. The first three inputs may be used to indicate the CP (the columns labeled 5-3) to be suppressed. The CS suppression circuit 747 may invert the first three inputs to determine the first physical column plane to suppress CS activation for a particular CS. For example, in the row for CS7:0, the inputs are “000.” Inverted, this is “111,” which corresponds to seven. Accordingly, as indicated by the final column, CS activation in physical CP07 is suppressed when any or all of CS0-7 are selected for activation. The CS suppression circuit 747 may add eight to the inverted input to determine the second physical column plane to suppress CS activation. Continuing the above example, “111” plus eight is “1111,” which corresponds to fifteen. Accordingly, as indicated by the final column, CS activation in physical CP15 is suppressed. This matches FIG. 8, where CS0-7 of CP07 and CP15 are blocked out.

Any suitable logic circuits may be used to implement table 900 in CS suppression circuit 747. In some embodiments, the remaining two inputs (the columns labeled 2-0) may be omitted. In other embodiments, the remaining to inputs may be used to provide additional information to the CS suppression circuit 747 and/or other components of the column decoder 745.

In some embodiments, CS suppression circuit 747 may include logic circuits to implement table 700 and table 900. In some embodiments, the mode register 775 may be programmed with a value that indicates which decoding scheme should be enabled. In a first state, the mode register 775 may provide a signal that enables logic circuits that implement table 700 and disables logic circuits that implement table 900. In a second state, the mode register 775 may provide a signal that enables logic circuits that implement table 900 and disables logic circuits that implement table 700. When metadata is stored in the memory array, the mode register 775 may disable both sets of logic circuits in some embodiments.

The memory devices according to the embodiments disclosed herein (e.g., memory devices 104, semiconductor device 200), may generate and store ECC data that may be used by an ECC circuit (e.g., ECC circuit 235, ECC circuit 332) to correct errors in data and/or metadata. Typically, ECC circuits can only correct and/or detect a certain number of errors in a set of bits. For example, some ECC circuits may be capable of correcting one error and detecting up to two errors in a set of data. The number of errors that can be corrected and/or detected may be based on a number of bits to be corrected and a number of parity bits generated.

There may be additional limits to the capabilities of system ECC circuits. For example, the system ECC circuit may be limited to correcting errors in certain portions of the data. For example, an ECC circuit may be capable of correcting an error in an upper nibble (e.g., four bits) or a lower nibble of a byte, but not an error that extends across the nibble. Thus, there may be a “fault line” between the upper and lower nibble. An error that crosses a fault line may not be able to be corrected by the ECC circuit. Accordingly, it is desirable to use techniques to prevent errors from “smearing” across fault lines to reduce the risk and/or frequency of uncorrectable errors. When errors are confined to either side of a fault line, may be referred to as a “bounded fault” implementation.

The locations of fault lines, such as between the upper and lower nibble line, may be based on various factors such as how the error correction data is generated, physical layout of the memory device, and/or other factors. According to embodiments of the present disclosure, the data for the virtual planes across the physical column planes may be mapped in a manner that reduces the risk of errors crossing fault lines. For example, data a virtual plane may be stored in one or more physical column planes, and when multiple physical column planes are used, all of the column planes are located on a same side of the fault line.

In some embodiments, the data may be mapped such that data for a virtual plane is stored in an upper nibble or a lower nibble of the memory device. Depending on the layout of the memory array, in some embodiments, this may include mapping the data for the virtual planes such that the data for each virtual plane is provided on word lines driven by subword line drivers that are associated with a same nibble. In some embodiments, mapping the data of the virtual planes across the physical column planes may provide a bounded fault-compliant implementation.

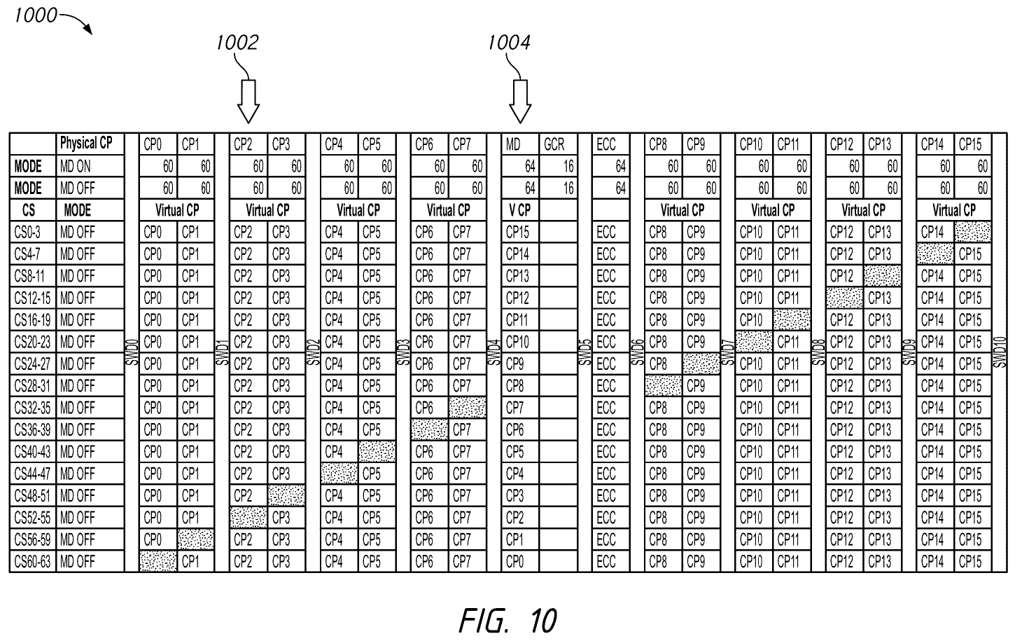

FIG. 10 shows a table indicating physical column plane suppression according to some embodiments of the present disclosure. The suppression scheme depicted in table 1000 may be used when a memory (e.g., one or more of memory devices 104 and/or semiconductor device 200) utilizes one metadata column plane.

The table 1000 may be substantially similar to table 600 shown in FIG. 6. In particular, the column plane suppression scheme is the same between both tables. However, in contrast to table 600, each physical column plane CP is only associated with data of a corresponding virtual plane. For example, as shown in the column indicated by arrow 1002, physical column plane CP2 is only associated with data for virtual column plane CP2, whereas in the arrangement in FIG. 6, physical column plane CP2 is associated with data for virtual column plane CP2 and CP1. The remaining data for each virtual plane CP0-15 is stored in the metadata plane in the column indicated by arrow 1004. This change does not require modification of the column suppression scheme shown in FIG. 6.

However, the mapping shown in table 1000 increases the risk of uncorrectable errors. For example, as shown in FIG. 10, data from the physical metadata plane is driven by the subword line driver SWD4, which is located between physical planes CP7 and MD. If SWD4 is defective, it may cause data to be improperly transmitted or received and/or stored data may have errors. Thus, data for a virtual plane stored in the physical metadata plane may be received with errors. While the metadata plane may store data associated with only four column select signals for each virtual plane, the error will occur in a different nibble than the rest of the data for half of the virtual planes. Accordingly, there is a greater risk that half of the virtual planes will have an uncorrectable error because the errors may be smeared across the upper and lower nibbles.

Returning to FIG. 6, the mapping of the data of the virtual planes to the physical column planes reduces the locations where errors smear across nibble boundaries. Accordingly, the mapping shown in table 600 may be preferrable to the mapping shown in table 1000 in some applications. However, while an improvement, the mapping shown in table 600 is not necessarily bounded fault-compliant when there is a lower nibble/upper nibble error fault line. In the mapping shown in FIG. 6, SWD4 receives data associated with virtual planes CP6, CP7, and CP8. If SWD4 transmits faulty data, errors may occur on both sides of a nibble fault line for data associated with CS0-31 because data for virtual plane CP8 crosses the upper and lower nibble boundary. Accordingly, the ECC circuit may not be able to correct the errors for virtual plane CP8.

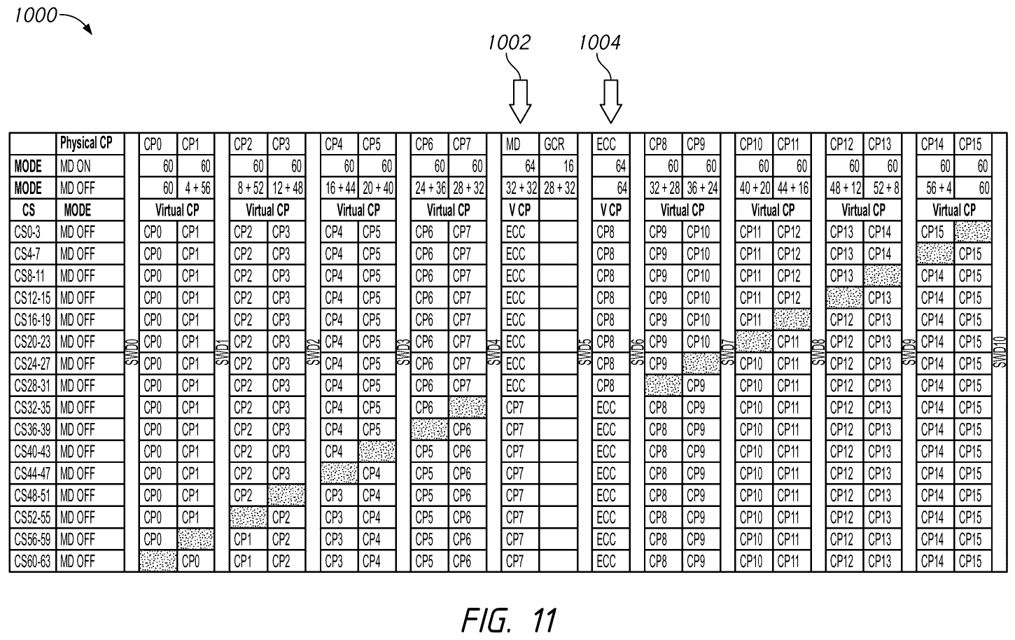

FIG. 11 shows a table indicating physical column plane suppression for a bounded fault implementation according to some embodiments of the present disclosure. The suppression scheme depicted in table 1100 may be used when a memory (e.g., one or more of memory devices 104 and/or semiconductor device 200) utilizes one metadata column plane.

The table 1100 may be substantially similar to table 600 shown in FIG. 6. In particular, the column plane suppression scheme is the same between both tables. However, in contrast to table 600, ECC data associated with CS0-31 is mapped to the physical metadata plane as shown in the column indicated by arrow 1102 and CP8 data associated with CS0-31 is mapped to the physical ECC plane as shown in the column indicated by arrow 1104. Remapping the data now allows a portion of the CP8 data to be provided to SWD5. This bounds the fault and prevents errors from crossing the nibble fault boundary. Because both the ECC plane and the MD plane include 64 column selects, no suppression is needed, and the remapping does not require modification of the suppression scheme.

It should be understood that FIG. 11 is merely an example of a bounded fault-compliant mapping of data of virtual planes to physical column planes. Other mappings may also provide bounded fault-compliant implementations. Further, depending on the number of virtual and physical column planes, memory layout (e.g., number and locations of subword drivers), and/or other factors (e.g., ECC algorithms used), other mappings may provided bounded fault-compliant implementations of virtual planes.

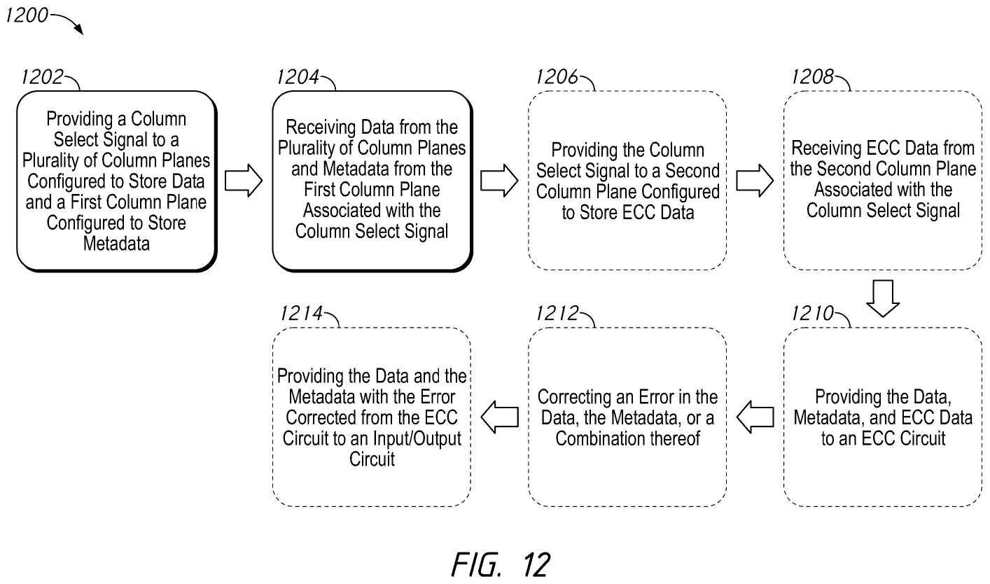

FIGS. 12-17 illustrate flow charts of examples of methods that may be performed according to embodiments of the present disclosure that allow for single pass access of data, metadata, and ECC data when storage of metadata is enabled, as well as access of data when storage of metadata is disabled. The methods may be performed in whole or in part by a computing system, such as computing system 100 shown in FIG. 1, a device, such as one or more of memory devices 104 in FIG. 1, semiconductor device 200 shown in FIG. 2, memory device 300 shown in FIG. 3, memory device 400 shown in FIG. 4, memory device 500 shown in FIG. 5, and/or memory device 701 shown in FIG. 7.

FIG. 12 is a flow chart of a method according to some embodiments of the present disclosure. The method illustrated in flow chart 1200 may allow for single pass access of data, metadata, and ECC data when storage of metadata is enabled, as well as access of data when storage of metadata is disabled according to some embodiments.

At block 1202, “providing a column select signal to a plurality of column planes configured to store data and a first column plane configured to store metadata” may be performed. In some embodiments, the providing may be performed by a column decoder, such as column decoder 245.

At block 1204, “receiving data from the plurality of column planes and metadata from the first column plane associated with the column select signal” may be performed. In some embodiments, sense amplifiers may receive the data and metadata, such as the sense amplifiers SAMP shown in FIG. 2 and sense amplifiers 320, 322, 324, and 326 shown in FIG. 3.

Optionally, the method shown in flow chart 1200 may further include block 1206 where “proving the column select signal to a second column plane configured to store error correction code (ECC) data” may be performed. The providing may be performed by the column decoder. The method may further include “receiving ECC data from the second column plane associated with the column select signal” which is performed at block 1208.

Optionally, the method shown in flow chart 1200 may further include “providing the data, metadata, and ECC data to an ECC circuit” as indicated by block 1210, “correcting an error in the data, the metadata, or a combination thereof,” as indicated by clock 1212. The data may be corrected by the ECC circuit based on the ECC data in some embodiments. The method may further include block 1214 where “providing the data and the metadata with the error corrected from the ECC circuit to an input/output circuit” is performed. In some embodiments, the data and/or metadata may be provided to a controller such as controller 106 and/or controller 202.

When a column plane has been repaired, the method shown in flow chart 1200 may include providing, from the column decoder, the column select signal to a global column redundancy (GCR) plane, and receiving, at the plurality of sense amplifiers, data or metadata from the GCR plane associated with the column select signal.

Optionally, the method may further include receiving a mode register write command and responsive to the mode register write command, writing a value to a mode register, wherein a state of the value configures the second plane to store the metadata. The mode register may be mode register 275 and/or 775 in some embodiments.

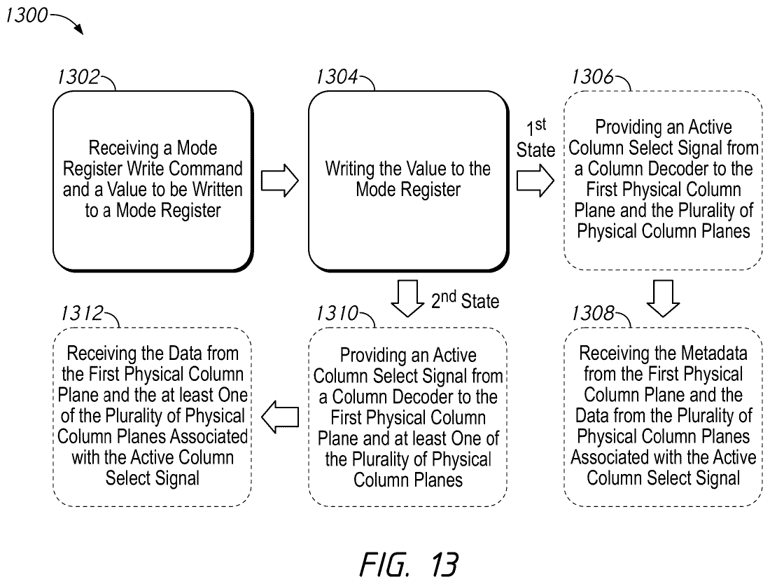

FIG. 13 is a flow chart of a method according to some embodiments of the present disclosure. The method shown in flow chart 1300 may allow physical column planes to be arranged to store data and metadata or arranged to store data. For example, as described with reference to FIGS. 3, 4, 5, 6, and 8, but not limited to those figures.

At block 1302, “receiving a mode register write command and a value to be written to a mode register” may be performed. The command may be received at a memory device from a controller in some embodiments. Responsive to the mode register write command, “writing the value to the mode register” may be performed at block 1304. In some embodiments, when the value is a first state, the method may include configuring a first physical column plane to store metadata and configuring a plurality of physical column planes to store data, and when the value is a second state, the method may further include configuring the first physical column plane and the plurality of physical column planes to store the data.

In some embodiments, configuring the first physical column plane and the plurality of physical column planes to store the data comprises configuring the first physical column plane and the plurality of physical column planes into a plurality of virtual planes. In some embodiments, configuring the plurality of virtual planes comprises providing a first set of column select signals from the first column plane to a first virtual plane of the plurality of virtual planes and providing a second set of column select signals from the first column plane to a second virtual plane. In some embodiments, all of the plurality of virtual planes are associated with column select signals from at least two different physical column planes.

Optionally, the method shown in flow chart 1300 may further include block 1306 where “providing an active column select signal from a column decoder to the first physical column plane and the plurality of physical column planes” is performed when the value is the first state. The method may further include “receiving the metadata from the first physical column plane and the data from the plurality of physical column planes associated with the active column select signal” as indicated by block 1308.

Optionally, the method shown in flow chart 1300 may further include block 1310 where “providing an active column select signal from a column decoder to the first physical column plane and at least one of the plurality of physical column planes” is performed when the value is the second state. The method may further include “receiving the data from the first physical column plane and the at least one of the plurality of physical column planes associated with the active column select signal” as indicated by block 1312.

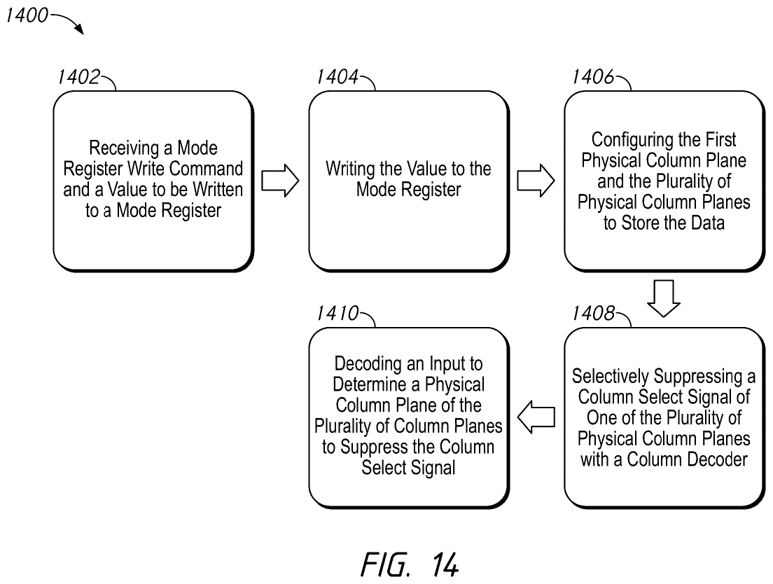

FIG. 14 is a flow chart of a method according to some embodiments of the present disclosure. The method shown in flow chart 1400 may provide a column select suppression scheme according to some embodiments of the present disclosure. For example, as described with reference to FIGS. 6 and 7, but not limited to those figures.

At block 1402 “receiving a mode register write command and a value to be written to a mode register” may be performed. Responsive to the mode register write command, at block 1404, “writing the value to the mode register” may be performed. When the value is a first state, the method may include configuring a first physical column plane to store metadata and configuring a plurality of physical column planes to store data.

When the value is a second state, the method shown in flow chart 1400 may further include “configuring the first physical column plane and the plurality of physical column planes to store the data” performed at block 1406, and “selectively suppressing a column select signal of one of the plurality of physical column planes with a column decoder” performed at block 1408. In some embodiments, the method in flow chart 1400 may include enabling the column decoder to perform the selectively suppressing when the value is the second state. In some embodiments, enabling the column decoder comprises providing an enable signal from the mode register to a column select suppression circuit of the column decoder. In some embodiments, when suppression is enabled, the column decoder provides an active column select signal to the first physical column plane and all but the one of the plurality of physical column planes. In some embodiments, the method includes disabling the column decoder from selectively suppressing the column select signal when the value is the first state.

Optionally, the method shown in flow chart 1400 may further include block 1410 where “decoding an input to determine a physical column plane of the plurality of column planes to suppress the column select signal” is performed. In some embodiments, decoding comprises inverting a plurality of binary inputs.

Optionally, the method shown in flow chart 1400 may further include receiving the data from the first physical column plane and all but the one of the plurality of physical column planes associated with the active column select signal. In some embodiments, the method shown in flow chart 1400 may further include providing the active column select signal to a second physical column plane configured to store error correction code (ECC) data, and receiving ECC data from the second physical column plane associated with the active column select signal. The method may further include providing the data and the ECC data to an error correction code (ECC) circuit and correcting an error in the data based on the ECC data in some embodiments.

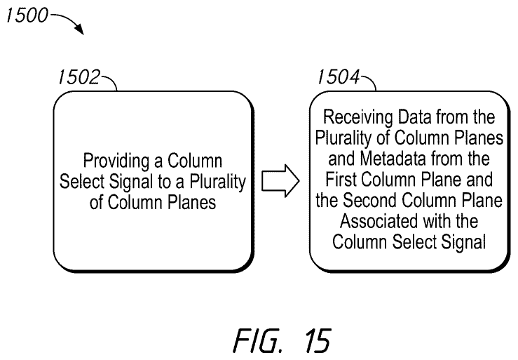

FIG. 15 is a flow chart of a method according to some embodiments of the present disclosure. The method shown in flow chart 1500 may implement an architecture where two physical planes are utilized to store metadata when metadata storage is enabled. Both metadata planes may be utilized to store data when metadata storage is disabled. For example, as described with reference to FIGS. 5, 8 and 9, but not limited to those figures.

At block 1502, “providing a column select signal to a plurality of column planes” may be performed. The providing may be performed by a column decoder in some embodiments. The column planes may be configured to store data and a first column plane and a second column plane may be configured to store metadata. At block 1504, “receiving data from the plurality of column planes and metadata from the first column plane and the second column plane associated with the column select signal” may be performed. In some embodiments, the data and metadata may be received at a plurality of sense amplifiers.

Optionally, the method shown in flow chart 1500 may further include receiving a mode register write command and a value to be written to a mode register, and responsive to the mode register write command, writing the value to the mode register. When the value is a first state, the method may include configuring the first column plane and the second column plane to store metadata and configuring a plurality of column planes to store data, and when the value is a second state, the method may include configuring the first column plane, the second column plane, and the plurality of column planes to store the data.

In some embodiments, configuring the first column plane, the second column plane, and the plurality of column planes to store the data comprises configuring the first column plane, the second column plane, and the plurality of column planes into a plurality of virtual planes. In some embodiments, configuring the plurality of virtual planes comprises providing a first set of column select signals from the first column plane to a first virtual plane of the plurality of virtual planes and providing a second set of column select signals from the second column plane to a second virtual plane. In some embodiments, wherein the first column plane and second column plane are each associated with sixty-four column select signals, each of the plurality of column planes are associated with sixty column select signals, and each of the plurality of virtual planes are associated with sixty-four column select signals.

In some embodiments, when storage of metadata is disabled (e.g., the value is the second state), the method may include selectively suppressing a column select signal of two of the plurality of column planes with a column decoder. In some embodiments, the method may further decoding an input to determine the two column planes of the plurality of column planes to suppress the column select signal, wherein the decoding comprises inverting a plurality of binary inputs to determine a first suppressed column plane and adding eight to the inverted plurality of binary inputs to determine a second suppressed column plane. In some embodiments, a number of the plurality of binary inputs is three. In some embodiments, a different pair of the plurality of column planes have the column select signal suppressed for a different set of column select signals from a plurality of column select signals. In some embodiments, a number of the plurality of column select signals is sixty-four, and each set of column select signals includes eight column select signals of the plurality of column select signals.

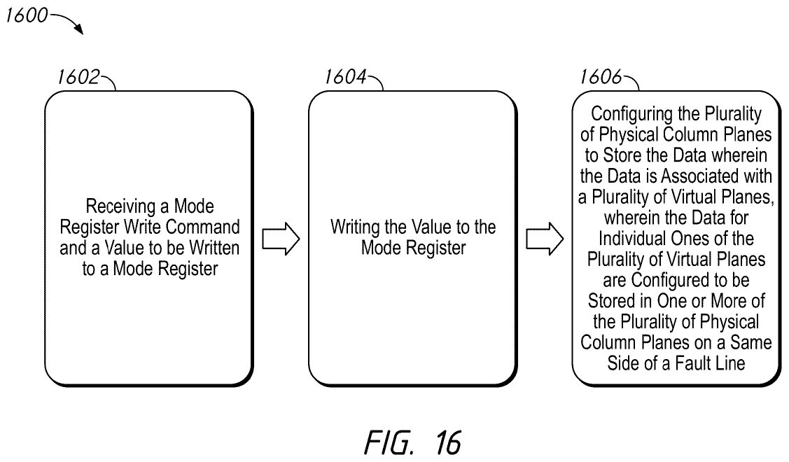

FIG. 16 is a flow chart of a method according to some embodiments of the present disclosure. The method shown in flow chart 1600 may map data associated with virtual planes to the physical column planes to reduce or eliminate uncorrectable errors by providing bounded fault implementations.

At block 1602, “receiving a mode register write command and a value to be written to a mode register” may be performed. At block 1604, responsive to the mode register write command, “writing the value to the mode register” may be performed. When the value is a first state, the method may include configuring a first physical column plane of a plurality of column planes to store metadata and configuring remaining ones of the plurality of physical column planes to store data. When the value is a second state, the method may include “configuring the plurality of physical column planes to store the data wherein the data is associated with a plurality of virtual planes, wherein the data for individual ones of the plurality of virtual planes are configured to be stored in one or more of the plurality of physical column planes on a same side of a fault line” as indicated by block 1606. In some embodiments, the fault line is located between a lower nibble and an upper nibble.

Optionally, the method in flow chart 1600 may further include storing data for the individual ones of the plurality of virtual planes in the one or more of the plurality of physical column planes associated with a same subword line driver in some embodiments. In some embodiments, the method in flow chart 1600 may further include storing data for the individual ones of the plurality of virtual planes in the one or more of the plurality of physical column planes associated with a one or more subword line drivers on the same side of the fault line.

Optionally, when value is the second state, the method in flow chart 1600 may further include storing the data of the plurality of virtual planes in the plurality of physical column planes, and storing error correction code (ECC) data associated with the data in an ECC plane. The method may further include providing the data associated with a virtual plane of the plurality of virtual planes and the ECC data corresponding to the virtual plane to an ECC circuit and correcting an error in the data with the ECC circuit based on the ECC data. In some embodiments, providing the data associated with the virtual plane comprises providing the data from two physical column planes of the plurality of column planes. In some embodiments, the error is on a first side or a second side of the fault line.

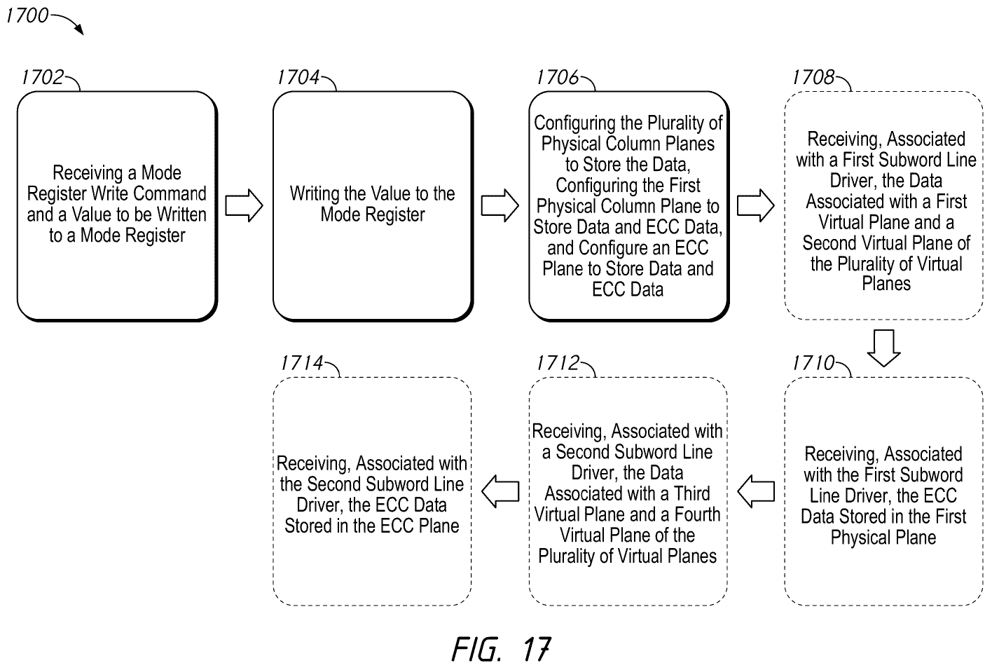

FIG. 17 is a flow chart of a method according to some embodiments of the present disclosure. The method shown in flow chart 1700 may utilize the ECC plane to provide a bounded fault-compliant implementation. For example, as described with reference to FIG. 11.

At block 1702, “receiving a mode register write command and a value to be written to a mode register” may be performed. Responsive to the mode register write command, “writing the value to the mode register” may be performed at block 1704. When the value is a first state, the method may include configuring a first physical column plane to store metadata and configuring a plurality of physical column planes to store data. When the value is a second state, the method may include “configuring the plurality of physical column planes to store the data, configuring the first physical column plane to store data and error correction code data (ECC), and configure an ECC plane to store data and ECC data” as indicated by block 1706. In some embodiments, configuring the first physical column plane, the ECC plane, and the plurality of physical column planes to store the data comprises configuring the first physical column plane, ECC plane, and the plurality of physical column planes into a plurality of virtual planes.

Optionally the method shown in flow chart 1700 may further include block 1708 where “receiving, associated with a first subword line driver, the data associated with a first virtual plane and a second virtual plane of the plurality of virtual planes” is performed and block 1710 and “receiving, associated with the first subword line driver, the ECC data stored in the first physical plane” is performed.

Optionally, the method shown in flow chart 1700 may further include block 1712 where “receiving, associated with a second subword line driver, the data associated with a third virtual plane and a fourth virtual plane of the plurality of virtual planes” is performed and block 1714 where “receiving, associated with the second subword line driver, the ECC data stored in the ECC plane” is performed.

In some embodiments, when the value is the first state, the method may include receiving, associated with a first subword line driver, the metadata associated with the first physical column plane and the data associated with a second physical column plane of the plurality of physical column planes, and receiving, associated with a second subword line driver, the ECC data associated with the ECC plane, and the data associated with a third physical column plane of the plurality of physical column planes.

Optionally, the method shown in flow chart 1700 may include activating a column select signal from column select signals 0-31, responsive to the column select signal, receiving data associated with a first virtual plane of the plurality of virtual planes from the ECC plane, and responsive to the column select signal, receiving ECC data from the first physical column plane. The method may further include activating a column select signal from column select signals 32-63, responsive to the column select signal, receiving data associated with a second virtual plane of the plurality of virtual planes from the first physical column plane, and responsive to the column select signal, receiving ECC data from the ECC plane. In some embodiments, the data is received associated with a first subword line driver, and the ECC data is received associated with a second subword line driver.

As disclosed herein, providing one or more additional column planes for metadata may allow metadata to be stored efficiently in the memory array and may permit data, metadata, and ECC data to be retrieved in a single pass. Further, utilizing virtual column planes, may allow flexibility to use more physical column planes to store data when no metadata is used.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array including a bank, wherein the bank includes a plurality of physical column planes; and
a mode register configured to store a value, wherein:
when the value is a first state, a first physical column plane of the plurality of physical column planes is configured to store metadata and remaining ones of the plurality of physical column planes are configured to store data,
wherein when the value is a second state, the plurality of physical column planes are configured to store the data, wherein the data is associated with a plurality of virtual planes, and
wherein the data for individual ones of the plurality of virtual planes are configured to be stored in one or more of the plurality of physical column planes on a same side of a fault line.

2. The apparatus of claim 1, wherein the fault line is located between an upper nibble and a lower nibble.

3. The apparatus of claim 1, wherein the memory array comprises a plurality of subword line drivers, and the one or more of the plurality of physical column planes provide the data associated with one or more of the plurality of subword line drivers on the same side of the fault line.

4. The apparatus of claim 1, wherein a number of the plurality of virtual planes is less than a number of the plurality of physical column planes.

5. The apparatus of claim 4, wherein the number of the plurality of virtual planes is sixteen and a number of the plurality of physical column planes is seventeen.

6. The apparatus of claim 1, wherein the plurality of physical column planes are each associated with a plurality of column select signals, wherein when the value is in the second state, the plurality of column select signals are associated with the plurality of virtual planes.

7. The apparatus of claim 6, wherein each of the plurality of virtual planes are associated with sixty-four column select signals of the plurality of column select signals.

8. The apparatus of claim 6, wherein a first one of the plurality of physical column planes is associated with sixty-four column select signals of the plurality of column select signals and remaining ones of the plurality of physical column planes are each associated with sixty column select signals of the plurality of column select signals.

9. The apparatus of claim 1, wherein the one or more of the plurality of physical column planes comprises two physical column planes.

10. The apparatus of claim 1, further comprising an error correction code (ECC) plane configured to store ECC data associated with the data and the metadata when the value is the first state and store ECC data associated with the data when the value is the second state.

11. The apparatus of claim 10, further comprising an ECC circuit configured to receive the data and the ECC data and correct errors in the data on a first side or a second side of the fault line based on the ECC data.

12. A system comprising:
a controller; and
a memory module comprising a plurality of memory devices, wherein at least one memory device of the plurality of memory devices comprises:
a memory array including a bank, wherein the bank includes a plurality of physical column planes; and
a mode register configured to store a value, wherein:
when the value is a first state, a first physical column plane of the plurality of physical column planes is configured to store metadata and remaining ones of the plurality of physical column planes are configured to store data,
wherein when the value is a second state, the plurality of physical column planes are configured to store the data, wherein the data is associated with a plurality of virtual planes, and
wherein the data for individual ones of the plurality of virtual planes are configured to be stored in one or more of the plurality of physical column planes on a same side of a fault line.

13. The system of claim 12, wherein the controller is configured to provide the value to the mode register.

14. The system of claim 12, wherein the controller receives a same number of bits of data when the value is the first state and when the value is the second state.

15. The system of claim 14, wherein the controller receives 128 bits of the data per cache line.

16. The system of claim 12, wherein the fault line is located between an upper nibble and a lower nibble.

17. The system of claim 12, wherein the memory array comprises a plurality of subword line drivers, and the one or more of the plurality of physical column planes provide the data associated with one or more of the plurality of subword line drivers on the same side of the fault line.

18. The system of claim 12, wherein the plurality of physical column planes are each associated with a plurality of column select signals, wherein when the value is in the second state, the plurality of column select signals are associated with the plurality of virtual planes.

19. The system of claim 18, wherein each of the plurality of virtual planes are associated with sixty-four column select signals of the plurality of column select signals.

20. The system of claim 18, wherein a first one of the plurality of physical column planes is associated with sixty-four column select signals of the plurality of column select signals and remaining ones of the plurality of physical column planes are each associated with sixty column select signals of the plurality of column select signals.

21. System of claim 12, further comprising an error correction code (ECC) plane configured to store ECC data associated with the data and the metadata when the value is the first state and store ECC data associated with the data when the value is the second state.

22. The system of claim 21, further comprising an ECC circuit configured to receive the data and the ECC data and correct errors in the data on a first side or a second side of the fault line based on the ECC data, wherein the controller is configured to receive the data corrected by the ECC circuit.

23. The system of claim 12, wherein a number of the plurality of memory devices is four, eight, or sixteen.

24. The system of claim 12, wherein the memory module comprises a dual in-line memory module and the at least one memory device comprises a dynamic random access memory device.

25. A method comprising:
receiving a mode register write command and a value to be written to a mode register;
responsive to the mode register write command, writing the value to the mode register;
when the value is a first state, configuring a first physical column plane of a plurality of physical column planes to store metadata and configuring remaining ones of the plurality of physical column planes to store data; and
when the value is a second state, configuring the plurality of physical column planes to store the data wherein the data is associated with a plurality of virtual planes, wherein the data for individual ones of the plurality of virtual planes are configured to be stored in one or more of the plurality of physical column planes on a same side of a fault line.

26. The method of claim 25, further comprising storing data for the individual ones of the plurality of virtual planes in the one or more of the plurality of physical column planes associated with a same subword line driver.

27. The method of claim 25, further comprising storing data for the individual ones of the plurality of virtual planes in the one or more of the plurality of physical column planes associated with a one or more subword line drivers on the same side of the fault line.

28. The method of claim 25, wherein the fault line is located between a lower nibble and an upper nibble.

29. The method of claim 25, wherein configuring the plurality of physical column planes to store the data is associated with the plurality of virtual planes comprises associating a plurality of column selects of the plurality of physical column planes with the plurality of virtual planes.

30. The method of claim 29, wherein a number of the plurality of virtual planes is less than a number of the plurality of physical column planes.

31. The method of claim 29, wherein sixty-four of the plurality of column select signals are associated with each of the plurality of virtual planes.

32. The method of claim 29, wherein a first physical column plane of the plurality of physical column planes is associated with sixty-four of the plurality of column select signals and remaining ones of the plurality of physical column planes are each associated with sixty of the plurality of column select signals.

33. The method of claim 25, when the value is the second state, the method further comprising:
storing the data of the plurality of virtual planes in the plurality of physical column planes; and
storing error correction code (ECC) data associated with the data in an ECC plane.

34. The method of claim 33, further comprising:
providing the data associated with a virtual plane of the plurality of virtual planes and the ECC data corresponding to the virtual plane to an ECC circuit; and
correcting an error in the data with the ECC circuit based on the ECC data.

35. The method of claim 34, wherein providing the data associated with the virtual plane comprises providing the data from two physical column planes of the plurality of column planes.

36. The method of claim 34, wherein the error is on a first side or a second side of the fault line.
